(19) United States
(12) Patent Application Publication
(10) Pub. No.: US 2022/0380206 A1
(43) Pub. Date: Dec. 1, 2022

(54) ELECTROMECHANICAL MICROSYSTEM

(71) Applicant: COMMISSARIAT A L'ENERGIE ATOMIQUE ET AUX ENERGIES ALTERNATIVES, Paris (FR)

(72) Inventors: Laurent MOLLARD, Grenoble Cedex (FR); Stéphane NICOLAS, Grenoble Cedex (FR); Damien SAINT-PATRICE, Grenoble Cedex (FR)

(73) Assignee: COMMISSARIAT A L'ENERGIE ATOMIQUE ET AUX ENERGIES ALTERNATIVES, Paris (FR)

(21) Appl. No.: 17/828,398

(22) Filed: May 31, 2022

(30) Foreign Application Priority Data
May 31, 2021 (FR) 21 05642

(51) Int. Cl. B81C 1/00; B81B 3/00

(52) U.S. Cl. CPC B81C 1/00158; B81B 3/0021; B81B 2203/0127; H04R 2201/003

(57) ABSTRACT

An electromechanical microsystem including an electromechanical transducer, a deformable diaphragm, a first cavity hermetically containing a deformable medium keeping a substantially constant volume under the action of an external pressure change and a second cavity. The deformable diaphragm forms a wall of the cavity and has at least one area freely deformable elastically. The free area also forms a wall of the second cavity. The electromechanical transducer is configured so that its movement depends on the external pressure change, and vice versa. A change in the external pressure in the first cavity induces a variation of the volume of the second cavity, or vice versa. Thus, the proposed electromechanical microsystem enables gripping of an object obstructing the opening of the second cavity and forms a microbarometer capable of converting at least one ambient pressure change into an electrical signal.

### TECHNICAL FIELD

The present invention relates to the fields of electromechanical microsystems. It finds application in gripping devices that allow capturing or expelling small-sized and/or lightweight objects. The invention also finds application in the field of contact detection or the field of ambient pressure variation detection. Thus, it could be implemented to make sensors.

### PRIOR ART

In many applications, it might be needed to capture or expel microscopic, and possibly nanoscopic, objects, and/or needed to detect the presence of such objects. There are microsystems that allow this.

In the case where these microsystems are actuators or gripping devices, their performances are assessed in particular on the following parameters: the amplitude of the movement, the exerted force, the accuracy of the generated movement or else the accuracy of the detection or the expulsion of an object. In the case where these microsystems are sensors, their performances are assessed in particular on their capability to detect a presence, and possibly a movement.

Moreover, whether the microsystems consist of actuators, gripping devices or sensors, what is aimed is that they offer good performances in terms of bulk and energy consumption.

All known solutions have low performances for at least one of these parameters. In general, the existing microsystems have performances that are too unsatisfactory for a combination of these parameters.

An object of the present invention is to provide an electromechanical microsystem which has improved performances in comparison with the existing solutions, at least for one of the above-mentioned parameters, or which has a better trade-off between at least two of the aforementioned parameters.

Another object of the present invention is to provide a microsystem which allows gripping a small-sized and/or lightweight object in a reliable and robust manner.

Another object of the present invention is to provide a microsystem which allows detecting an ambient pressure variation.

The other objects, features and advantages of the present invention will appear upon examining the following description and the appended drawings. It goes without saying that other advantages could be incorporated.

### SUMMARY

To achieve this objective, according to one embodiment, an electromechanical microsystem is provided comprising:
at least one electromechanical transducer comprising a portion movable between a balance position, off-load, and an out-of-balance position, under load,
at least one deformable diaphragm,
a first deformable cavity, delimited by walls, at least one portion of the deformable diaphragm forming at least one portion of a first wall selected amongst said walls of the first cavity, the first cavity being configured to hermetically contain a deformable medium capable of keeping a substantially constant volume under the action of a change of an external pressure exerted on the deformable medium through one of the walls of the first cavity,
at least one second deformable cavity, having a variable volume delimited by walls and an opening.

The movable portion of the electromechanical transducer is configured so that its movement depends on said change in the external pressure, or conversely its movement induces a change in the external pressure in the first cavity.

Said at least one portion of the deformable diaphragm has at least one free area freely deformable, preferably elastically, as a function of said change in the external pressure.

At least one portion of a first wall selected amongst said walls of the second cavity is formed by at least one portion of said at least one free area of the diaphragm, so that a change in the external pressure in the first cavity induces a variation of the volume of the second cavity, or conversely a variation of the volume of the second cavity induces a change in the external pressure in the first cavity.

Thus, the provided electromechanical microsystem allows gripping of an object obstructing the opening of the second cavity or consists of a microbarometer adapted to convert at least one change in the ambient pressure into an electric signal.

The opening of the second cavity is intended to be alternately obstructed and cleared by an object.

Hence, the microsystem allows gripping an object. Indeed, the variation of the volume of the second cavity induces a pressure difference in the second cavity when the latter is obstructed and thus allows holding or expelling the object obstructing the cavity. More particularly, an increase in the volume of the second cavity obstructed by the object induces a decrease in the pressure in the second cavity allowing sucking the latter and thus holding it. Conversely, a decrease in the volume of the second cavity obstructed by the object induces an increase in the pressure in the second cavity allowing releasing, and possibly expelling, the object.

Another aspect of the invention relates to a set comprising an electromechanical microsystem as introduced hereinabove and at least one object intended to obstruct the opening. It may consist of an object to be grasped or to be expelled by the electromechanical microsystem. Preferably, the lateral wall defines a distal end and the opening is formed at least partially by the distal end of the lateral wall.

According to one example, the entirety of the distal end of the lateral wall is shaped so that, when the object obstructs the opening, a deformation of the deformable diaphragm tending to increase the volume of the second cavity creates a decrease in the pressure in the second cavity.

According to one example, the distal end of the lateral wall is shaped so that the cooperation of the object and of the distal end ensures enough air tightness of the second cavity to create a pressure drop when the volume of the second cavity increases under the effect of a deformation of the deformable diaphragm.

Another aspect of the invention relates to a method for manufacturing an electromechanical microsystem as introduced hereinabove, comprising, and possibly being limited to, deposition and etching steps, quite common in the microelectronics industry. Indeed, the electromechanical microsystem may be manufactured by common means of the microelectronics industry, which confers on its manufacturer all of the advantages resulting from the use of these means, including a great flexibility in terms of sizing, energy of adhesion between the different deposits, thickness of the different deposits, extent of etching, etc.

According to one example, the method for manufacturing the electromechanical microsystem comprises the following steps:
a step of forming, over a substrate, at least one portion of said at least one electromechanical transducer, then
a step of depositing the deformable diaphragm, then
a step of forming at least one first open cavity over the deformable diaphragm, then
a step of filling with the deformable medium and closing the first cavity, and
a step of etching the substrate to form a second open cavity and a front face of the electromechanical microsystem comprising the second cavity.

### BRIEF DESCRIPTION OF THE FIGURES

The aims, objects, as well as the features and advantages of the invention will appear better from the detailed description of embodiments of the latter which are illustrated by the following appended drawings wherein:

FIG. 1A is a block diagram of a sectional view or of a section of an electromechanical microsystem according to a first embodiment of the invention. In FIG. 1A, the electromechanical microsystem is illustrated in a configuration wherein the diaphragm is not deformed.

FIG. 1B represents a top view of the electromechanical microsystem according to the first embodiment of the invention illustrated in FIG. 1A.

FIG. 1C represents a top view of a variant of the embodiment of the invention illustrated in FIG. 1B.

FIG. 2A is a block diagram of a sectional view or of a section of an electromechanical microsystem according to a second embodiment of the invention. In FIG. 2A, the electromechanical microsystem is illustrated in a configuration wherein the diaphragm is not deformed.

FIG. 2B represents a top view of the electromechanical microsystem according to the second embodiment of the invention illustrated in FIG. 2A.

FIG. 3A is a block diagram of a sectional view of an electromechanical microsystem according to the first embodiment of the invention and of an object to be grasped. In FIG. 3A, the electromechanical microsystem is illustrated in a configuration wherein the diaphragm is not deformed.

FIG. 3B is a block diagram of a sectional view of the microsystem illustrated in FIG. 3A, in a first deformation configuration of the diaphragm.

FIG. 3C is a block diagram of a sectional view of the microsystem illustrated in FIG. 3A, in a second deformation configuration of the diaphragm.

FIGS. 4A and 4B illustrate an embodiment of the microsystem according to the first embodiment of the invention, FIG. 4A illustrates the state of the microsystem when it is affixed on the object to be grasped and FIG. 4B illustrates the state of the microsystem when it has grasped the object.

FIG. 5 is a more detailed diagram than that of FIG. 1A and representing an electromechanical microsystem that is structurally close to that one illustrated in FIG. 1A.

FIGS. 6 to 12 schematically represent steps of an example of a method for manufacturing the electromechanical microsystem illustrated in FIG. 5.

The drawings are provided as examples and do not limit the invention. They consist of schematic principle representations intended to facilitate understanding of the invention and are not necessarily to the scale of practical applications. In particular, the thicknesses of the different illustrated layers, walls and members do not necessarily represent reality.

### DETAILED DESCRIPTION

According to one example, the diaphragm having an inner face configured to be in contact with the deformable medium and an outer face, the inner face of the diaphragm forms at least one portion of the first wall of the first cavity and the outer face of the diaphragm forms at least one portion of the first wall of the second cavity. Thus, by construction, the deformable diaphragm of the second cavity forms at least one portion of the bottom of the second cavity.

According to one example, an area over which extends the first wall of the second cavity is devoid of any movable portion of an electromechanical transducer. Thus, we benefit better from the effect of hydraulic amplification on the variation of the volume of the second cavity.

According to one example, the microsystem further comprises a flexible layer, for example based on a material selected amongst silicon and parylene, configured to be interposed between at least one of the walls of the second cavity and a portion of the object obstructing the second cavity.

According to one example, the second cavity comprises, amongst its walls, a lateral wall extending from a perimeter of its first wall opposite to the first cavity. Preferably, the lateral wall is solid and non-deformable in comparison with the deformation capacity of the free area of the deformable diaphragm. Thus, the hermeticity of the second cavity when it is obstructed by the object is ensured. It is also ensured that the integrity of the microsystem and of the object, in particular when one is affixed on the other, is preserved. It is further ensured that the second cavity has a volume that is sufficient and could be parameterised as a function of the extent of its lateral wall, so that any volume variation desired depending on the targeted application could be reached. More particularly, by its shape and/or its dimensions, the lateral wall allows defining a larger volume of the second cavity than its absence. Thus, deformations with a higher amplitude of the deformable diaphragm at its free area are made possible, before the deformed diaphragm projects from the opening of the second cavity, in particular when the transducer is configured to deform the diaphragm in a direction opposite to the centre of the first cavity.

Complementarily to the previous example, the opening of the second cavity may be formed by the distal end of the lateral wall. The distal end of the lateral wall of the second cavity is opposite to the first cavity, its proximal end may extend from a wall of the first cavity. It is over this distal end of the lateral wall that the flexible layer could be deposited.

According to one example, the first wall of the second cavity is formed by only one portion of said at least one free area of the diaphragm, the second cavity comprising a lateral wall extending from said at least one free area of the diaphragm.

According to one example, the microsystem further comprises a plurality of second cavities separated from each by a non-zero distance. In the case where several second cavities extend from the same wall of the first cavity, it is possible to distribute the forces exerted on an object obstructing the second cavities at different locations of the object or over different surfaces of the object. Furthermore, the electromechanical microsystem is thus made resilient to a possible dysfunction of a second cavity, and possibly of several second cavities. In addition, the conditions of placing the object with respect to the microsystem so that the object could be held may be eased. Moreover, whether several second cavities extend from the same wall of the first cavity or from different walls of the first cavity, the microsystem could thus allow holding and releasing a plurality of objects, each object obstructing at least one second cavity of the plurality.

According to one example, the movable portion of at least one electromechanical transducer is configured so that loading thereof induces its movement towards the centre of the first cavity, a deformation of the free area of the deformable diaphragm opposite to the centre of the first cavity and therefore a decrease in the volume of the second cavity and so that a subsequent absence of loading induces its movement opposite to the centre of the cavity, a deformation of the free area of the deformable diaphragm towards the centre of the first cavity and therefore an increase in the volume of the second cavity. Thus, it is possible to hold an object obstructing the second cavity without having to load the electromechanical transducer while holding the object. Furthermore, the object could be released, and possibly expelled, by loading the electromechanical transducer again.

According to one example, said at least one electromechanical transducer is configured so as to selectively induce a decrease and an increase of the volume of the second cavity.

According to one example, said at least one electromechanical transducer may be secured to the deformable diaphragm over an area located outside the free area, and more particularly over an area remote from the free area, so that any movement of the movable portion of the transducer induces a stretching or a relaxation of the deformable diaphragm.

According to one example, when loaded, said at least one electromechanical transducer is configured to exert on the deformable medium a determined change in the external pressure and wherein the shape and/or the dimensions of said at least one free area of the deformable diaphragm are configured so as to induce, according to said determined change in the external pressure, a variation of the volume of the second cavity adapted to generate a force sucking an object obstructing the opening higher which is higher than the weight of the object. The microsystem according to this feature finds a particular application in so-called “pick-and-place” type machines.

In the case where the electromechanical microsystem comprises the movable portion of a unique electromechanical transducer and a unique free area, said at least one portion of one of the walls of the second cavity is formed at least partially by the unique free area with the exception of the movable portion of the unique electromechanical transducer. Nonetheless, in absolute terms, at least one portion of at least one of the walls of the second cavity may be formed at least partially at least by the movable portion of at least one electromechanical transducer.

According to one example, the free area forms a disk, an ellipse or a polygon.

According to one example, the electromechanical microsystem comprises a plurality of electromechanical transducers.

According to one embodiment, the electromechanical transducers are separated from each other. Their movable portions are not in contact.

According to one example, an electromechanical transducer surrounds, at least partially, and possibly entirely, one or several other electromechanical actuator(s), in particular their movable portion. Furthermore, they may be actuated independently from each other.

Preferably, each electromechanical transducer has a movable portion configured so that its movement depends on said change in the external pressure, or conversely so that its movement induces a change in the external pressure exerted on the deformable medium through one of the walls of the cavity.

Thus, the electromechanical microsystem includes several electromechanical transducers for a first cavity.

According to one example, at least some of the electromechanical transducers of said plurality are configured so that, under load, their movable portions induce deformations of the free area of the diaphragm.

Thus, at least some of these electromechanical transducers allow deforming the free area of the diaphragm with a determined amplitude. The overall deformation of the free area results from a cumulated displacement of the movable portions of these electromechanical transducers. Thus, the electromechanical microsystem has a step-by-step operation. This allows controlling, step-by-step, and/or with a great accuracy, the depression or the overpressure created in the second cavity. Otherwise, this could allow increasing the amplitude of the variation of the volume of the second cavity and/or limiting the control voltage of the electromechanical transducers.

The electromechanical transducers may be loaded simultaneously or successively. The amplitude of deformation of the free area induced by each electromechanical transducer may be identical or different.

According to one example, at least some of the electromechanical transducers of said plurality are configured so that, under load, their movable portions, induce deformations of the free area of the diaphragm in two opposite directions.

Thus, at least two of these electromechanical transducers allow deforming the free area according to two opposite directions. Hence, these two electromechanical transducers are antagonist. Thus, at least one of these electromechanical transducers allows creating a depression in the second cavity and at least another one of these electromechanical transducers allows creating an overpressure in the second cavity.

These two antagonist electromechanical transducers may be separated from each other by a non-zero distance. Alternatively, one of these electromechanical transducers may surround the other electromechanical transducer, preferably entirely. According to another embodiment, the same transducer allows performing these two alternating movements. For this purpose, it is possible to use a transducer made of AlN for example.

According to one example, the electromechanical microsystem comprises several free areas, separated from each other by a non-zero distance.

These free areas may be formed by the same diaphragm. Alternatively, these free areas may be formed by distinct diaphragms.

According to one example, the free area is freely deformable, preferably elastically, as a function of said change in the external pressure.

Preferably, the electromechanical microsystem as introduced hereinabove is devoid of any optical element, such as a lens, in particular a variable-focus one.

According to one example, at least one portion of the electromechanical transducer forms a portion of the wall of the cavity which is partially formed by the deformable diaphragm. According to this feature, the electromechanical microsystem has a structure that is not open-through, leaving the other walls of the cavity free so as to be able implement other functions therein or so as to enable them to remain inert, for an increased integration capability in particular in a “pick-and-place” type machine.

According to one example, the electromechanical transducer extends, directly over the deformable diaphragm, i.e. the electromechanical transducer is directly in contact with the deformable diaphragm. Alternatively, the electromechanical transducer extends indirectly over the deformable diaphragm, i.e. at least one element or one intermediate layer is disposed between the electromechanical transducer and the deformable diaphragm. Preferably, the electromechanical transducer extends around the free area of the deformable diaphragm.

In particular, in the case where the microsystem comprises several electromechanical transducers, one of the transducers may have an annular shape whose circular centre defines the extent of the free area of the deformable diaphragm.

The movable portion of the electromechanical transducer may have a surface at least twice as large, and possibly 5 times larger, and preferably at least ten times larger than the surface of the free area of the deformable diaphragm, and possibly than the surface of the free areas of the deformable diaphragm. The larger the surface of the transducer in comparison with the surface of the free area, the higher will be the amplitude of deformation of the free area of the diaphragm.

Preferably, the deformable diaphragm is configured so that its free area could be deformed with an amplitude of at least 50 μm, possibly of at least 100 μm, and possibly of at least 1,000 μm according to a direction perpendicular to the plane in which the wall of the first cavity formed by the deformable diaphragm primarily extends. Thus, without tearing and/or without any significant wear, the electromechanical microsystem offers the ability to address numerous and various application requiring a large pressure variation, the latter being defined where appropriate by the considered technical field.

According to one example, at least one portion of the electromechanical transducer forms a portion of said first wall of the cavity.

The electromechanical microsystem may further comprise a bottom stop supported by the wall of the first cavity opposite to the free area of the deformable diaphragm, said bottom stop extending in the first cavity towards the free area. It has a shape and dimensions configured to limit the deformation of the free area of the deformable diaphragm so as to protect the deformable diaphragm, and more particularly its free area, in particular from a possible pull-out, when the object and the microsystem are affixed to each other. Otherwise, the bottom stop is shaped so as to limit the contact surface between the diaphragm and the wall of the first cavity opposite to the free area of the deformable diaphragm. Alternatively or complementarily, the bottom stop is shaped so as to limit the contact surface between the diaphragm and the wall of the first cavity opposite to the free area of the deformable diaphragm. This allows avoiding the diaphragm adhering to this wall.

The electromechanical transducer may be a piezoelectric transducer, preferably comprising a PZT-based piezoelectric material.

The deformable medium hermetically contained in the first cavity may comprise at least one amongst a fluid and a liquid, the deformable medium preferably having a viscosity in the range of 100 cSt at ambient temperature and pressure.

According to a non-limiting embodiment, the deformable medium has a compressibility comprised between 10⁻⁹ and 10⁻¹⁰ Pa⁻¹ at 20° C., for example in the range of 10⁻¹⁰ Pa⁻¹ at 20° C., without these values being restrictive.

The electromechanical microsystem as introduced hereinabove may further comprise a plurality of deformable diaphragms and/or a plurality of free areas per deformable diaphragm. For example, at least one free area is remote from, preferably not contiguous to, a wall of the second cavity.

The electromechanical transducer may be powered by electric voltages produced with neighbouring electronic circuit.

A “microsystem” is a system whose outer dimensions are smaller than 1 centimetre (10⁻² metres) and preferably than 1 millimetre (10⁻³ metres).

An electromechanical transducer serves as an interface between the mechanical and electrical domains. An electromechanical transducer may comprise a movable portion between a balance position, off-load, and an out-of-balance position, under load. In the case where the transducer is piezoelectric, the load is electric.

When mention is made of the centre of the cavity, this centre is defined geometrically by considering the centre of a cavity having a non-deformed free area of the deformable diaphragm.

By “lower” and “higher”, it should be understood “lower than or equal to” and “higher than or equal to”, respectively. Equality is excluded by the use of the terms “strictly lower” and “strictly higher”.

By a parameter “substantially equal to/higher than/lower than” a given value, it should be understood that this parameter is equal to/higher than/lower than the given value, more or less 20%, possibly 10%, of this value. By a parameter “substantially comprised between” two given values, it should be understood that this parameter is at least equal to the lowest given value, more or less 20%, possibly 10%, of this value, and at most equal to the highest given value more or less 20%, possibly 10%, of this value.

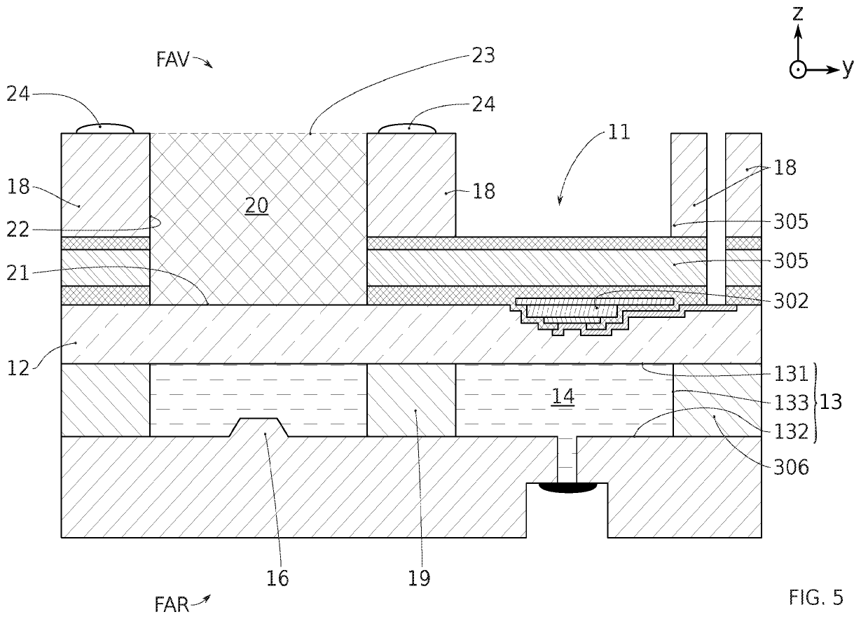

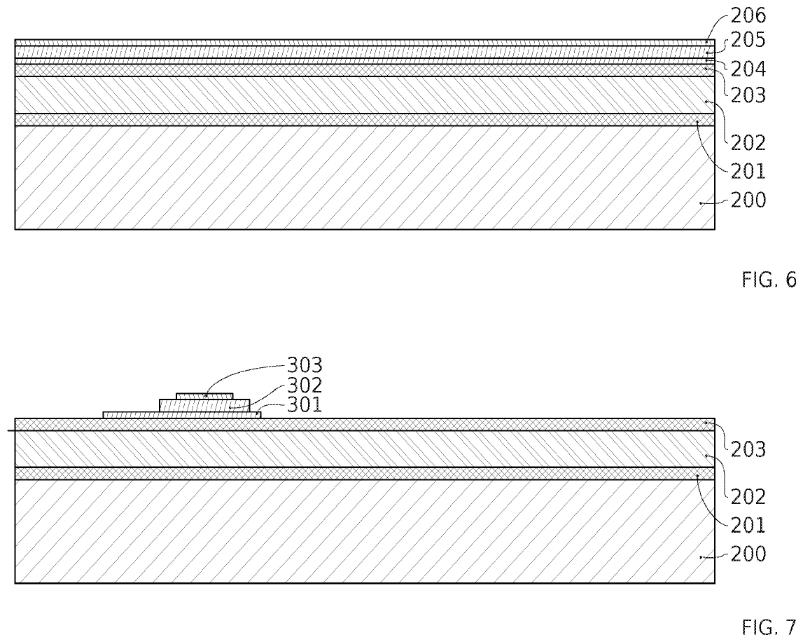

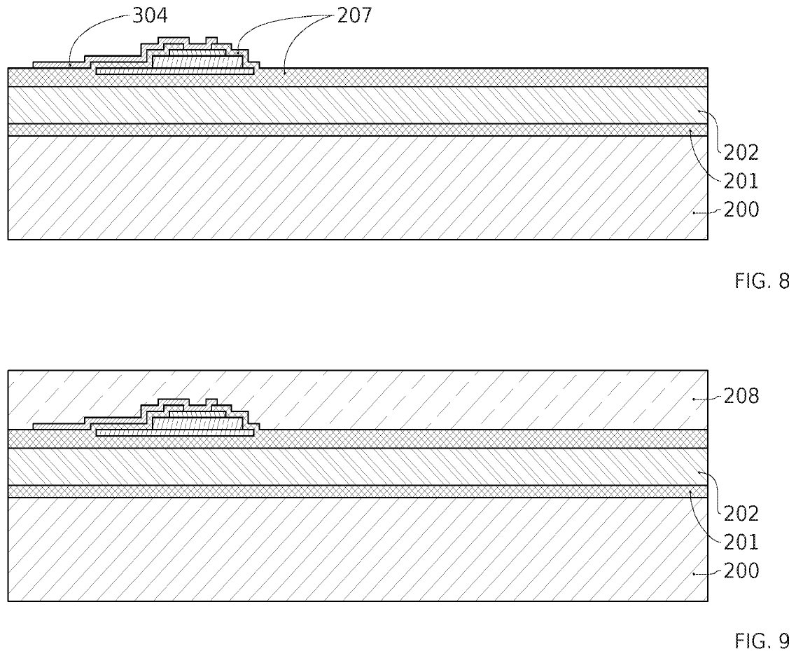

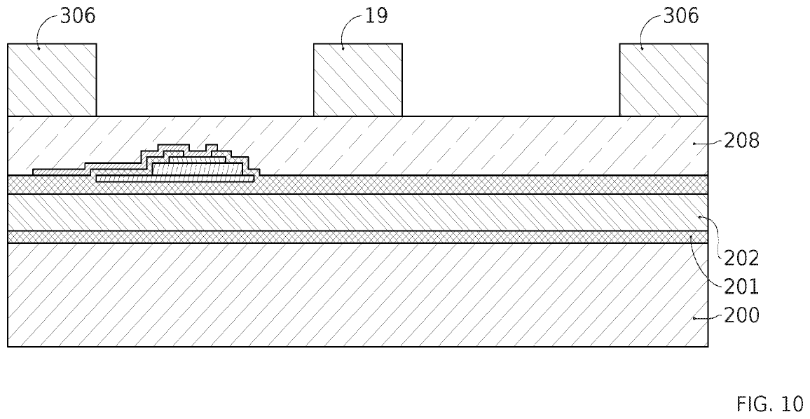

As this will be described in more details later on, depending on its configuration and its use, the electromechanical microsystem 1 according to the invention may ensure several functions:
As a gripping device, it could allow grasping or expelling an object 3 as illustrated in FIGS. 3A to 3C and 4A to 4B.
As a sensor, it could in particular allow detecting an ambient pressure variation.

The features allowing ensuring these different functions will now be described in details with reference to the figures.

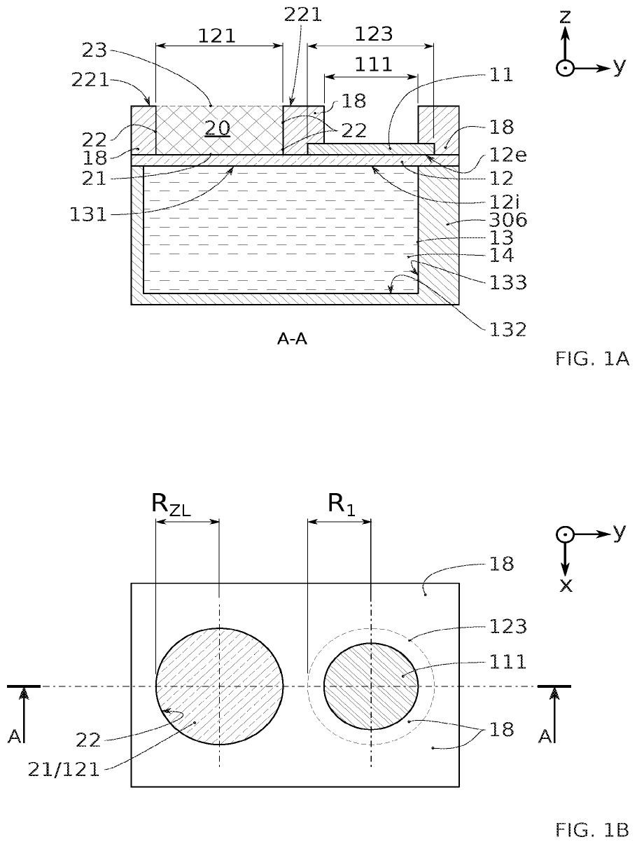

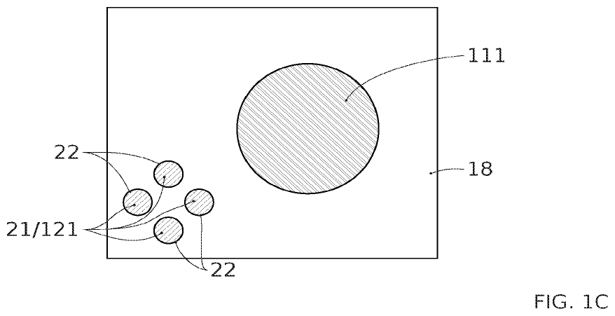

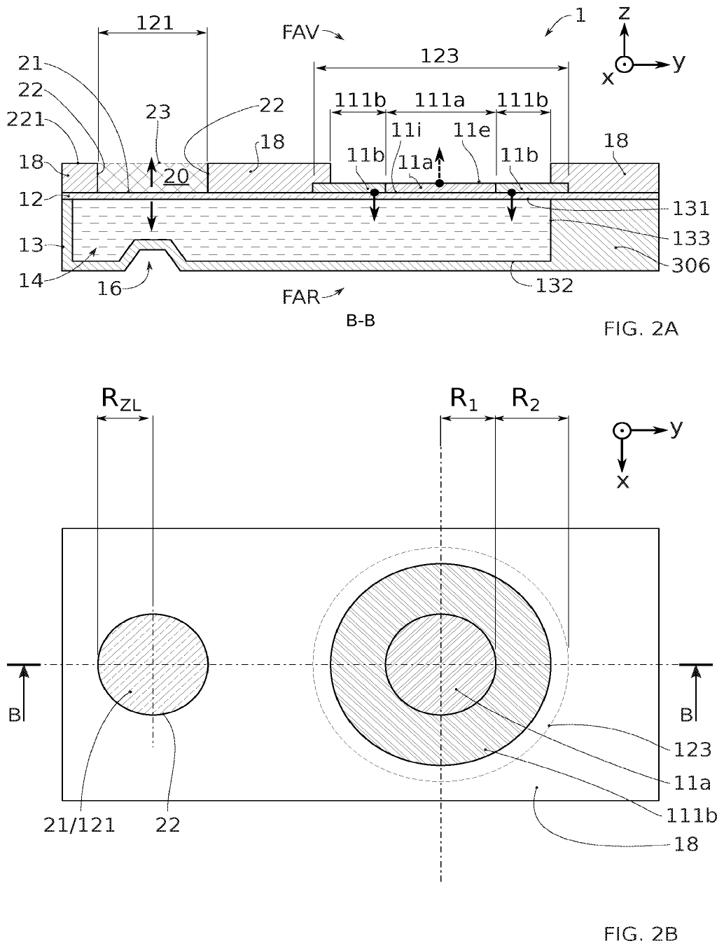

FIG. 1A is a block diagram of a first embodiment of the electromechanical microsystem 1 according to the invention. FIGS. 3A to 3C illustrate the electromechanical microsystem of FIG. 1A, during use according to a first operating mode. FIGS. 4A and 4B illustrate the electromechanical microsystem of FIG. 1A, during use according to a second operating mode.

In FIG. 1A, an electromechanical transducer 11, a deformable diaphragm 12, a first cavity 13 configured to hermetically contain a deformable medium 14 and a second cavity 20 having a volume delimited by walls 21, 22 and an opening 23, are illustrated. The deformable diaphragm 12 has an area 121 freely deformable under the action of a change in the external pressure exerted on the deformable medium 14. The deformation of the free area 121 of the deformable diaphragm 12 allows varying the volume of the second cavity 20.

Before describing the different embodiments of the invention illustrated in the figures in more details, note that each of these illustrations schematically represents an embodiment of the electromechanical microsystem which has a structure that is not open-through. More particularly, in the different illustrated embodiments, each electromechanical transducer 11, 11a, 11b and the deformable diaphragm 12 is located at the front face FAV of the electromechanical microsystem 1. This structure type is particularly advantageous to the extent that the rear face FAR of the electromechanical microsystem 1 could participate only in a passive manner, and in particular without being deformed, in the function of the electromechanical microsystem 1.

More particularly, the rear face FAR of an electromechanical microsystem 1 with a structure that is not open-through according to the invention may, in particular, form a face by which the electromechanical microsystem 1 could be easily mounted on a support and/or may form a face by which the electromechanical microsystem could be easily functionalised further. In the case where the electromechanical microsystem 1 is mounted on a support, this support may, for example, be a support that is movable in three dimensions of the space or known to have a so-called 2.5 dimensional mobility. Such a movable support may be part of a so-called “pick-an-place” machine.

Nonetheless, the invention is not limited to electromechanical microsystems with a structure that is not open-through. The invention also relates to so-called electromechanical microsystems 1 with an open-through structure wherein at least one electromechanical transducer 11, 11a, 11b and the deformable diaphragm 12 are arranged over distinct walls of the cavity 13, whether these walls are adjacent or opposite to each other.

Electromechanical Transducer 11, 11a and 11b

Each electromechanical transducer 11, 11a, 11b comprises at least one movable portion 111, 111a, 111b. The latter is configured so as to move or be moved between at least two positions. A first one of these positions is in a balance position reached and held when the electromechanical transducer 11, 11a, 11b is not loaded, for example whether by an electric voltage or by a force urging it off its balance position. A second position of the movable portion 111, 111a, 111b of the electromechanical transducer 11, 11a, 11b is reached when the electromechanical transducer 11, 11a, 11b is loaded, for example whether by an electric voltage or by a force urging it off its balance position. The electromechanical transducer 11, 11a, 11b could be kept in either one of the above-described first and second positions, and thus have a binary behaviour, or could further be kept in any intermediate position between tis balance position and its largest deflection position, with respect to equilibrium.

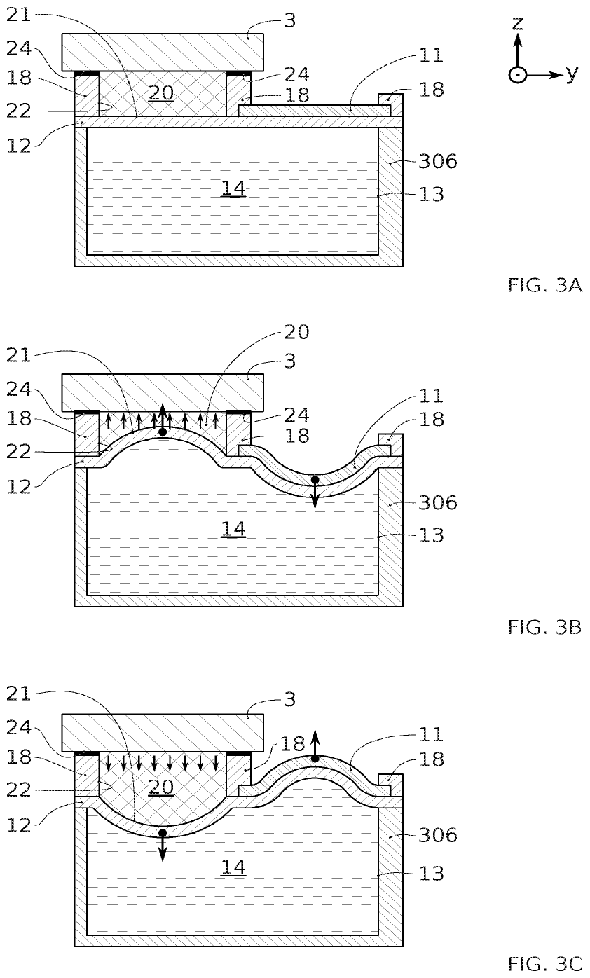

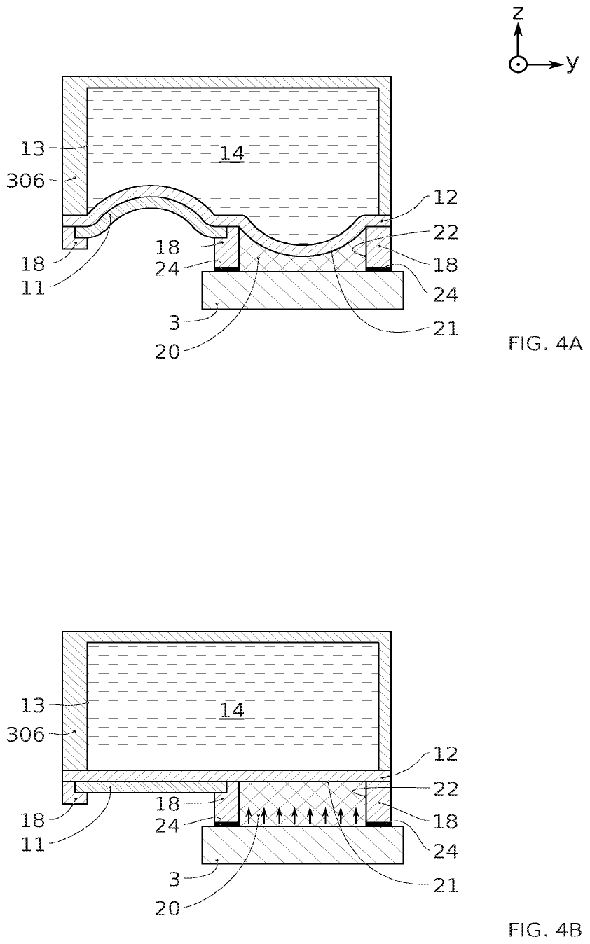

In the examples illustrated in FIGS. 1A and 2A, it is possible to consider that, when the electromechanical transducer 11, 11a, 11b is not loaded, its movable portion 111, 111a, 111b extends primarily in a plane parallel to the plane xy of the orthogonal reference frame xyz.

Preferably, at least one, and possibly each electromechanical transducer 11, 11a, 11b is a piezoelectric transducer. Each electromechanical transducer 11 comprises at least one piezoelectric material mechanically coupled to another element, described as a support or beam. The term beam does not limit, in any manner whatsoever, the shape of this element.

In a known manner, one property of a piezoelectric material is to be stressed when subjected to an electric field. When stressed, it is deformed. Mechanically associated to the support, the piezoelectric material seizes the support with it and then displaces the latter. The area of the support that could be displaced corresponds to the movable portion 111, 111a, 111b of the electromechanical transducer 11, 11a, 11b. It is this displacement property that is used to form an actuator.

Similarly, under the action of a mechanical stress, a piezoelectric material is electrically polarised. Thus, when the support is moved, it deforms the piezoelectric material which induces an electric signal. It is this property that is used to form a sensor.

Hence, from this example, yet this remains possibly true for each of the other considered embodiments of the electromechanical transducer 11, 11a, 11b, it arises that the electromechanical microsystem 1 according to the invention could operate as a gripping device and/or as a sensor.

Even more preferably, at least one, and possibly each, electromechanical transducer 11, 11a, 11b is a piezoelectric transducer comprising a PZT-based (lead zirconate titanate) piezoelectric material. In this case, the movable portion 111, 111a, 111b of the electromechanical transducer 11 could, under load, move with a more significant displacement (because of the piezoelectric coefficient d31) than with many other piezoelectric materials. Nonetheless, PZT being a ferroelectric material, such a piezoelectric transducer preferably operates in one single actuation direction (movement of its movable portion 111, 111a, 111b in one direction) irrespective of the polarity of its electric power supply, while a piezoelectric transducer based on a non-ferroelectric material could preferably operate in both directions (movement of its movable portion 111, 111a, 111b in two opposite directions). Alternatively or complementarily, at least one, and possibly each, electromechanical transducer 11, 11a, 11b may be a (non-ferroelectric) piezoelectric transducer based on a material adapted to enable its movable portion 111, 111a, 111b to move in opposite directions with respect to its balance position, for example as a function of the polarity of its electric power supply. For example, such a material is a material based on aluminium nitride (AlN).

Deformable Diaphragm 12

The deformable diaphragm 12 may be based on a polymer, and is preferably based on PDMS (standing for polydimethylsiloxane). The properties of the deformable diaphragm 12 in particular its thickness, its surface area and its shape may be configured so as to confer on the deformable diaphragm 12, and more particularly on the area 121 of this diaphragm which is freely deformable, a targeted stretch capacity, in particular according to the targeted application.

First Cavity 13

As illustrated in particular in FIGS. 1A and 2A, the first cavity 13 has more particularly walls 131, 132, 133 hermetically containing the deformable medium 14. In the illustrated examples, the wall 132 of the first cavity 13 forms the rear face FAR of the electromechanical microsystem 1. The wall 131 opposite to the wall 132 is formed at least partially by at least one portion of the deformable diaphragm 12. Thus, the wall 131 is deformable. Next, the wall 131 is sometimes referred to as the first wall of the first cavity 13. It is located at the front face FAB of the electromechanical microsystem 1. At least one lateral portion 133 joins the walls 131 and 132 together. It should be noted that the hermeticity of the first cavity 13 requires the deformable diaphragm 12 being itself watertight, or made watertight, in particular at its free area 121. Preferably, the walls 132, 133 remain fixed when the diaphragm is deformed.

In turn, the deformable medium 14 could keep a substantially constant volume under the action of a change in the external pressure. In other words, it may consist of an incompressible or barely compressible medium the deformation of which preferably requires little energy. For example, it consists of a liquid.

Since at least one portion of the first wall 131 of the first cavity 13 is formed by at least one portion of the deformable diaphragm 12, it should be understood that any change in the external pressure exerted on the deformable medium 14 could be compensated by a substantially proportional deformation of the deformable diaphragm 12, and more particularly of its free area 121 and/or by a displacement of the movable portion 111, 111a, 111b of at least one electromechanical transducer 11, 11a, 11b. When a transducer is loaded, this compensation is more particularly related to a conversion of the change in the external pressure exerted on the deformable medium 14 into a stretching of the deformable diaphragm 12 or a relaxation of the already stretched deformable diaphragm 12. It should be recalled that the deformable medium 14 is non-compressible and that these stresses are therefore imparted with a conservation of the volume of the first cavity 13. It should be understood that, for reasons relating to the repeatability of the actuation or of the detection of the movement allowed by the electromechanical microsystem 1 according to the invention, it is preferably that any deformation of the deformable diaphragm 12 is elastic, and not plastic, in order to guarantee the return of the deformable diaphragm 12 to the same minimum stretch or maximum relaxation state, once it is no longer stressed.

As illustrated in each of FIGS. 1A and 2A, each electromechanical transducer 11, 11a, 11b may form a portion of the first wall 131 of the first cavity 13. Thus, each electromechanical transducer 11, 11a, 11b and the deformable diaphragm 12 are placed on the same side of the first cavity 13. Advantageously, as mentioned hereinabove, the structures having this feature are not open-through.

In these non-limiting examples, the diaphragm 12 has an inner face 12i configured to be in contact with the deformable medium 14 and an outer face 12e. The inner face 12i forms at least one portion of the first wall 131 of the first cavity 13. Each electromechanical transducer 11, 11a, 11b as an inner face 11i directed opposite, and preferably in contact with, the outer face 12e of the diaphragm 12. Each electromechanical transducer 11, 11a, 11b also has an outer face 11e, opposite to the inner face 11i, and directed towards the outside of the electromechanical microsystem 1. Alternatively, it is possible to provide for one or several intermediate layer(s) being disposed between the outer face 12e of the diaphragm 12 and the inner face 11i of each electromechanical transducer. The electromechanical microsystem 1 is configured so that the movement of the movable portion 111, 111a, 111b of each electromechanical transducer 11, 11a, 11b causes a deformation of the free area 121 of the diaphragm 12 and therefore of the first wall 131 which encloses the medium 14.

Notice that, in each of FIGS. 1A and 2A, the deformable diaphragm 12 separates each electromechanical transducer 11, 11a, 11b from the deformable medium 14.

Furthermore, each electromechanical transducer 11 or each pair of electromechanical transducers 11a and 11b may advantageously be secured to the deformable diaphragm 12 over an area 123 so that any movement of the movable portion 111, 111a, 111b of each electromechanical transducer 11, 11a, 11b induces, in particular over this area 123, a stretching or a relaxation of the deformable diaphragm 12. Thus, in the example illustrated in FIG. 2A, when the first electromechanical transducer 11a is loaded so as to move upwards (as illustrated by the arrow in dotted line extending from the movable portion 111a of the first electromechanical transducer 11a), a decrease in the external pressure exerted on the deformable medium 14 is observed, which induces the stretching of the deformable diaphragm 12 downwards, i.e. towards the centre of the first cavity 13.

As illustrated in FIGS. 1B, 1C and 2B, the area 123 over which extends each of the electromechanical transducers 11, 11a and 11b is located outside the free area 121. It may also be adjacent to the free area 121. It may also delimit the area 121, for example by partially or completely surrounding it.

Deformable Medium 14

More particularly, the deformable medium 14 may comprise at least one amongst a fluid and/or a liquid. The parameters of the deformable medium 14 will be adapted according to the targeted applications. Thus, it is ensured that any change in the external pressure exerted on the deformable medium 14 induces a substantially proportional deformation of the free area 121 of the deformable diaphragm 12. The deformable medium 14 may consist of or be based on a liquid, such as oil, or consist of or be based on a polymer. According to one example, the deformable medium 14 is based on or consists of glycerine. Thus, in addition to a substantially proportional deformation of the diaphragm 12, the capability of the deformable medium 14 to occupy in particular the volume created by stretching of the free area 121 of the deformable diaphragm 12 opposite to the centre of the first cavity 13 is ensured

In the case where the electromechanical microsystem 1 serves as a gripping device, at least one electromechanical transducer 11, 11a, 11b is loaded so as to exert a change in the external pressure on the deformable medium 14 and therefore induce the deformation of the deformable diaphragm 12. Conversely, when the electromechanical microsystem 1 serves as a sensor, the deformation of the diaphragm 12 exerts a change in the external pressure on the deformable medium 14 which induces a displacement of the movable portion 111, 111a, 111b of at least one electromechanical transducer 11, 11a, 11b and consequently generates an electric signal.

The outer perimeter of the free area 121 and/or of the transducer 11 illustrated in FIG. 1A and/or of the set of transducers 11a, 11b as illustrated in FIG. 2A, may be defined for example by a cowl 18 which holds the diaphragm 12. Thus, the diaphragm 12 is located between the cowl 18 and the deformable medium 14. For example, this cowl 18 extends in the plane xy. It has at least one opening which defines the free area 121. The cowl 18 may extend over the entire surface of the first cavity 13, projected on the plane xy, except for an opening defining the free area 121 of the diaphragm 12 and for at least one other opening corresponding substantially to the area 123 in which the electromechanical transducer 11 or the set of two transducers 11a, 11b is accommodated. The cowl 18 may have an area that separates these two openings.

Arrangement of the Free Area 121

In the embodiments illustrated in FIGS. 1A, 1B, 1C, 2A and 2B, the free area 121 is separated from electromechanical transducer 11 or from the set of transducers 11a and 11b. Thus, a non-zero distance separates the free area 121 and each electromechanical transducer 11, 11a, 11b. For example, this non-zero distance is at least partially materialised by the cowl 18, as illustrated in FIG. 2B.

According to other embodiments not illustrated in the figures, the free area 121 may be surrounded, at least partially, by at least one electromechanical transducer 11, 11a, 11b. Nonetheless, in this case, it will be ensured that the configuration of the electromechanical microsystem 1 is not such that the volume of the second cavity 20 does not vary irrespective of the change in the position of the electromechanical transducer(s) 11, 11a and 11b.

More specifically, in the example illustrated in FIGS. 2A and 2B, the first electromechanical transducer 11a is in the form of a disk with a radius R1 and the second electromechanical transducer 11b is in the form of a ring extending in an area with a radial extent R2 around the disk formed by the first electromechanical transducer 11a.

Preferably, the sum of the radius R1 of the disk formed by the first electromechanical transducer and of the radial extent R2 of the ring formed by the second electromechanical transducer is smaller than 900 μm, preferably smaller than 600 μm, and even more preferably smaller than 300 μm.

The radius R1 of the disk formed by the first electromechanical transducer 11a may be at least 20 μm, and the radial extent R2 of the ring formed by the second electromechanical transducer 11b may be at least 10 μm.

Complementarily or alternatively, the radial extent R2 of the ring formed by the second electromechanical transducer 11b may be about twice as small as the radius R1 of the disk formed by the first electromechanical transducer 11a.

Complementarily or alternatively to any one of the previous two examples, said at least one first electromechanical transducer and said at least one second electromechanical transducer tightly fit within a circular area with a determined radius called “total radius” and denoted Rₜₒₜ, said circular area being composed of two portions, a first portion in the form of a disk centred on said circular area and a second portion in the form of a ring extending around the first portion. Said at least one first electromechanical transducer fits more particularly within the first portion of the circular area and said at least one second electromechanical transducer fits more particularly within the second portion of the circular area. The first portion of the circular area has a radius R_{2/3} substantially equal to two thirds of the total radius and the second portion of the circular area has a radial extent E_{1/3} substantially equal to one third of the total radius.

Preferably, the disk 11a and the ring 11b are concentric.

As represented, the disk 11a and the ring 11b may be adjacent to each other, the ring 11b then having a radial extent equal to R2.

For example, the radial extent R2 of the area extending around the disk 11a is comprised between a few tens and a few hundred microns, and typically equal to 100 microns for a total radius in the range of 300 μm.

It should be understood herein that each electromechanical transducer 11a, 11b comprising a movable portion 111a, 111b of its own, the movable portion of one of the two transducers 11a and 11b may be loaded independently from, and in particular alternately with, the movable portion of the other one of the two transducers 11a and 11b.

In a configuration according to which, R1 is substantially equal to ⅔ of R1+R2 and R2 is substantially equal to ⅓ of R1+R2, the deformation of the movable portion 111a of the first electromechanical transducer 11a is antagonist, and more particularly in an opposite direction along the axis z, to the deformation of the movable portion 111b of the second electromechanical transducer 11b. Even in the case where each of the two transducers 11a and 11b comprises a PZT-based piezoelectric transducer, it is then possible to alternately induce, depending on which one of the two transducers 11a and 11b is loaded, a separation and an approach of the free area 121 of the diaphragm 12 relative to at least one wall amongst the walls 132, 133 of the first cavity 13. For example, the first electromechanical transducer 11a is configured so as to move upwards, i.e. opposite to the centre of the first cavity 13, when it is loaded, and the second electromechanical transducer 11b is configured so as to move downwards, i.e. towards the centre of the first cavity 13, when it is loaded.

Note that none of the electromechanical transducers 11, 11a and 11b is limited to an axisymmetric shape, but could have other shapes, and in particular an oblong or oval shape, a triangular, rectangular shape, etc.

In the case illustrated in FIG. 1A and where the electromechanical transducer 11 is a piezoelectric transducer comprising a PZT-based piezoelectric material, it is interesting that the movable portion 111 of the electromechanical transducer 11 has a surface at least twice, and possibly four times, and even ten times, as larger than the surface of the free area 121 of the deformable diaphragm 12. Henceforth, the deformable diaphragm 12 is configured so that its free area 121 is capable of being deformed with an amplitude of at least 50 μm, of about 100 μm, and possibly of several hundred μm.

In general, the deformable diaphragm 12 is configured so that its free area 121 is capable of being deformed with an amplitude smaller than 1 mm. This deformation is measured according to a direction perpendicular to the plane in which the outer face 12e of the diaphragm 12 primarily extends at rest. Without tearing and/or without any significant wear, the electromechanical microsystem 1 allows for a hydraulic amplification of the action and thus offers the capability to address numerous and various applications requiring a large displacement, or equivalently large variations of the volume of the second cavity 20. In this context, the electromechanical microsystem 1 illustrated in FIGS. 3A to 3C and 4A to 4B may be defined as a gripping device with large force variations.

Also, in the case where the partial overlap of the deformable diaphragm 12 by the electromechanical transducer 11 is as illustrated in FIGS. 1A and 1B and the electromechanical transducer 11 is a piezoelectric transducer comprising a PZT-based piezoelectric material, the radius R_{ZL} of the free area 121 of the deformable diaphragm 12 may be substantially equal to 100 μm and the radial extent R1 of the electromechanical transducer 11 (typically its radius if it is circular) may be substantially equal to 350 μm. The references R_{ZL} and R1 are illustrated in FIG. 1B.

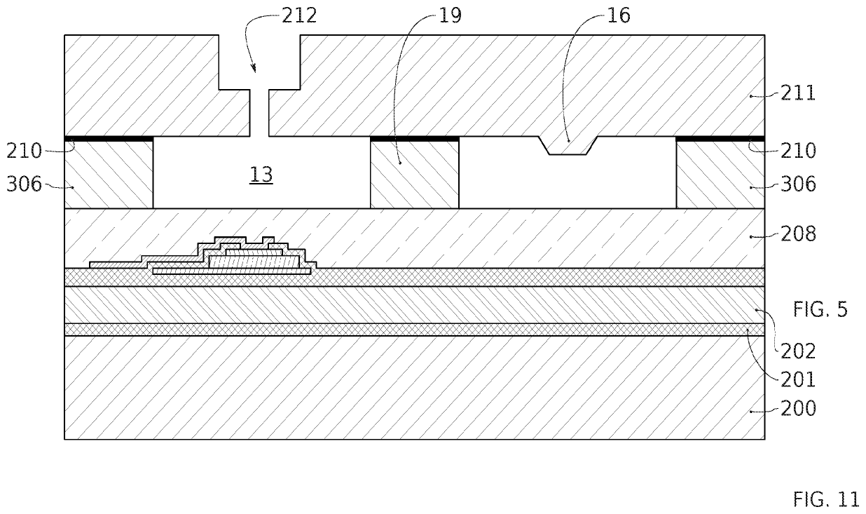

As mentioned hereinabove, the electromechanical transducer 11 may comprise, more particularly, an element forming a beam 305 and a PZT-based piezoelectric element 302, the latter being configured to induce a deflection of the beam 305 (Cf. FIG. 5). The thickness of the piezoelectric element 302 may be substantially equal to 0.5 μm and the thickness of the beam 305 may be comprised for example between a few microns and several tens microns, for example 5 μm. In such a configuration, in the case where the radius of the electromechanical transducer 11 is larger than 100 microns, and possibly larger than 200 μm, the amplitude of displacement of the movable portion 111 of the transducer 11 may reach a value equal to a few tens microns, in particular when the transducer 11 is subjected to an electric voltage equal to a few tens volts. More particularly, in such a configuration, the movable portion 111 of the electromechanical transducer 11 may be displaced or deflected with an amplitude for example substantially equal to 15 μm when subjected to an electric voltage for example substantially equal to 10 V.

Nonetheless, the invention is not limited to the different specific values given hereinabove which could be substantially adapted, depending on the targeted application, in particular to find a trade-off between the stretch factor and the expected amplitude of deformation of the free area 121 of the deformable diaphragm 12.

It should be noted that, in its balance position, the movable portion 111 of the electromechanical transducer 11, and more generally the electromechanical transducer 11, could be not flat, but could, on the contrary, have a deflection called balance deflection which does not deprive the electrically-powered electromechanical transducer 11 in any manner from its capability to move or deflect, in terms of amplitude.

Second Cavity 20

The second cavity 20 will now be described in particular with reference to each of FIGS. 1A and 2A.

The second cavity 20 is deformable. It has a variable volume delimited by walls 21, 22 and an opening 23. In each of FIGS. 1A and 2A, the wall 22 extends from the first cavity 13 up to a distal end 221. The opening 23 is formed by the distal end 221 of the lateral wall 22. In FIG. 1A, the distal end 221 is represented to illustrate the embodiment wherein the wall 22 is partially formed by the cowl 18 described hereinbelow.

More particularly, at least one portion of a first wall 21 selected amongst said walls 21, 22 of the second cavity 20 is formed by at least one portion of said at least one free area 121 of the diaphragm 12. Thus, and in particular in each of the two embodiments illustrated in the figures, a change in the external pressure in the first cavity 13 induces a variation of the volume of the second cavity 20, or conversely a variation of the volume of the second cavity 20 induces a change in the external pressure in the first cavity 13.

Even more particularly, as illustrated in each of FIGS. 1A and 2A, the inner face 12i of the diaphragm 12 forms at least one portion of the first wall 131 of the first cavity 13 and the outer face 12e of the diaphragm forms at least one portion of the first wall 21 of the second cavity 20.

The first wall 21 of the second cavity 20 may be formed by only one portion of the free area 121 of the diaphragm 12. The second cavity 20 then comprises a lateral wall 22 extending from said at least one free area 121 of the diaphragm 12. The lateral wall 22 then defines the extent of the first wall 21 of the second cavity 20 with respect to the extent of the free area 121 of the diaphragm 12. In this case, the walls 21 and 22, as well as the opening 23, of the second cavity 20 are displaced, in particular according to the direction z illustrated in FIGS. 1A and 2A, when the free area 121 of the diaphragm 12 is deformed. The microsystem according to this particularity may allow accommodating the contact between the second cavity 20 and an object 3 intended to obstruct the second cavity 20. Thus, the risk of damage, and possibly of pull-out, of the free area 121 of the diaphragm 12 upon said contact is reduced. Note that, in this case, the volume variation of the second cavity 20 is due to the deformation of only the portion of the free area 121 which defines the extent of the first wall 21 of the second cavity 20.

Moreover, the area over which extends the first wall 21 of the second cavity 20 may be devoid of any movable portion 111, 111a, 111b of an electromechanical transducer 11, 11a, 11b, as illustrated in the figures. Nonetheless, the invention is not limited to such an exemption. In particular, at least one portion of the walls 21, 22 of the second cavity 20 may comprise at least the movable portion 111, 111a, 111b of an electromechanical transducer 11, 11a, 11b provided that the configuration of the electromechanical microsystem 1 is not such that the volume of the second cavity 20 does not vary irrespective of the change in the position of the electromechanical transducer(s) 11, 11a, 11b.

Amongst these walls 21, 22, the second cavity 20 comprises a lateral wall 22 extending from a perimeter of its first wall 21 opposite to the first cavity 13. Preferably, the lateral wall 22 is solid and non-deformable in comparison with the deformation capacity of the free area 121 of the deformable diaphragm 12.

In FIGS. 1A and 2A, a cowl 18 is illustrated. Indeed, the lateral wall 22 of the second cavity 20 may be defined, across the thickness of the cowl 18, by an opening formed in the cowl 18 to define the free area 121. Also note that it is possible to provide for the free area 121 of the diaphragm 12 being configured, together with one or several electromechanical transducer(s), to be deformed only towards the centre of the first cavity. Thus, the volume variations of the second cavity are not necessarily limited to variations smaller than the volume defined by the outer face 12e of the deformable diaphragm at rest and the opening formed in the cowl 18 to define the area 121.

Nonetheless, the second cavity 20 advantageously comprises a lateral wall 22 extending from a perimeter of its first wall 21 opposite to the first cavity 13, where appropriate beyond the thickness of the cowl 18 itself. Thus, it is ensured that a volume extending possibly significantly one both sides of the first wall 131 of the first cavity 13 is conferred on the second cavity 20. Thus, depending on its extent, such a lateral wall 22 allows defining a second cavity 20 having a sufficient and configurable volume when the free area 121 of the diaphragm 12 is at rest. Thus, all volume variations, desirable depending on the targeted application, could be reached.

More particularly, by its shape and/or its dimensions, the lateral wall 22 allows defining a substantially large volume of the second cavity 20, when the free area 121 of the diaphragm 12 is at rest, thus allowing for a broad capability of adaptation of the volume variation reached for various applications.

The cowl 18 may be shaped so as to form or lateral extend the lateral wall 22. Thus, the cowl 18 may form a portion of the cavity 20. Alternatively, the lateral wall 22 may extend from the cowl 18, opposite to the centre of the cavity 13. Note herein that the main function of the cowl 18 is to contribute in trapping the non-movable portion of at least one electromechanical transducer, to better ensure the non-movability thereof; it then extends, as illustrated in FIGS. 1A and 2A in particular, over the non-movable portion of the transducer 11 and/or over the non-movable portion of both transducers 11a and 11b. We will see later on that this contribution in trapping the non-movable portion of at least one electromechanical transducer by the cowl 18 may be complete by a spacer 306 or a strut 19, located opposite to the cowl 18 with respect to said non-movable portion.

The electromechanical microsystem 1 according to the invention may further comprise a flexible layer 24 (illustrated in the FIGS. 3A to 3C and 4A to B, as well as in FIG. 5) configured to be interposed between at least one of the walls 21, 22 of the second cavity 20 and a portion of the object 3 obstructing the second cavity 20. For example, the flexible layer 24 is based on a material selected amongst silicon and parylene. It is intended, on the one hand, to dampen, where appropriate, the contact between the opening 23 of the second cavity 20 and an object 3 obstructing this opening 23 and, on the other hand, to ensure sealing of the second cavity 20 at the contact between the second cavity 20 and the object 3.

It should be understood that such a flexible layer 24 is not necessarily required when the electromechanical microsystem 1 forms all or part of a microbarometer.

Furthermore, the electromechanical microsystem 1 may comprise, as illustrated in FIG. 1C, a plurality of second cavities 20 separated from each other by a non-zero distance.

In the case where several second cavities 20 extend from the same wall 131 of the first cavity 13, as illustrated in FIG. 1C, each of these second cavities 20 may be configured to participate in holding and releasing an object 3 obstructing them. Thus, it is allowed to distribute the forces exerted on the object 3 at different locations of the object or on different surfaces of the object. These different surfaces are neither necessarily comprised in the same plane nor necessarily parallel to each other, such variations could be accommodated by the shapes and/or the dimensions of the lateral walls 22 of the second cavities 20, and more particularly by the shapes and/or the dimensions of their distal ends 221.

Furthermore, the electromechanical microsystem is thus made resilient to a possibly dysfunction of a second cavity 20, and possibly of several second cavities; indeed, a plurality of second cavities 20 allows limiting the risks of loss of sealing and thus the loss of the pressure difference enabling the suction or the expulsion of the object.

Moreover, the conditions of placing the object 3 relative to the microsystem 1 so that the object 3 could be held may be relaxed. For example, if the object 3 is not affixed opposite a portion of the second cavities of the plurality, holding and/or expulsion thereof could nevertheless be ensured.

Moreover, whether several second cavities 20 extend from the same wall of the first cavity 13 or from different walls of the first cavity 13, the microsystem 1 could thus allow holding and releasing a plurality of objects 3, each object obstructing at least one second cavity 20 of the plurality.

The distal end 221 of the lateral wall 22 of each second cavity 20 may be shaped so as to conform to the shape of an object 3 intended to obstruct the opening 23, and more particularly to a specific area of this object 3. Thus, it is possible to ensure a determined positioning, in particular in terms of orientation, of the grasped object.

Bottom Stop

As illustrated in each of FIGS. 2A and 5, the electromechanical microsystem 1 may further comprise one or several stop(s) at the end of travel, called bottom stops 16. This or these bottom stop(s) 16 are supported by the wall 132 of the first cavity 13 which is opposite to the wall 131 formed at least partially by the deformable diaphragm 12. It extends in the first cavity 13 towards the free area 121 of the deformable diaphragm 12. Preferably, this bottom stop 16 has a shape and dimensions configured to limit the contact surface between the diaphragm 12 and the wall 132 of the cavity 13 opposite to the free area 121 of the deformable diaphragm 12. This allows avoiding the diaphragm 12 adhering and sticking to this wall 132.

### Embodiment of FIGS. 3A to 3C

Referring to FIGS. 3A to 3C, a first operating mode of the microsystem 1 according to its first embodiment will now be described.

The electromechanical transducer 11 illustrated in FIGS. 3A to 3C is configured so as to alternately induce a decrease and an increase of the volume of the second cavity 20.

As illustrated in FIG. 3A, an object 3 may be affixed on the microsystem 1 so as to obstruct the opening 23 of the second cavity 20, when the free area 121 of the diaphragm 12 is not deformed.

As illustrated in FIG. 3C, the electromechanical transducer 11 may be loaded so as to be deflected, as indicated by the arrow, in a direction opposite to the centre of the first cavity 13. This change in the position of the transducer 11 then induces a deformation of the free area 121 of the diaphragm 12 towards the centre of the first cavity 13. The volume of the second cavity 20 then increases. Therefore, the pressure inside the second cavity 20 is reduced in comparison with the ambient pressure. Thus, a pressure difference is created which tends to hold the object 3 on the microsystem 1.

In the case where the deflection direction of the transducer 11 could be reversed, as illustrated in FIG. 3B, the change in the position of the transducer 11 then induces a deformation of the free area 121 of the diaphragm 12 opposite to the centre of the first cavity 13. The volume of the second cavity 20 then decreases. Therefore, the pressure inside the second cavity 20 is increased in comparison with the ambient pressure. Thus, a pressure difference is created which tends to expel the object 3 off the microsystem 1.

This operation of the microsystem according to the first embodiment of the invention may be obtained while considering one single electromechanical transducer based on a material adapted to enable the movable portion 111, 111a, 111b of the electromechanical transducer to move in opposite directions with respect to its balance position, for example as a function of the polarity of its electric power supply. As already set out hereinabove, such a material is for example a material based on aluminium nitride (AlN).

The same operation may be obtained while considering at least two electromechanical transducers 11a and 11b, each based on a material adapted to enable the movable portion 111a, 111b of the electromechanical transducer to which it belongs to move in one direction with respect to its balance position. The first electromechanical transducer 11a may be in the form of a disk with a radius denoted R1 and the second electromechanical transducer 11a may be in the form of a ring with a radial extent denoted R2 (Cf. FIG. 2B). The radial extent R2 of the ring formed by the second electromechanical transducer 11b will then be selected about two times smaller than the radius R1 of the disk formed by the first electromechanical transducer 11a.

### Embodiment of FIGS. 4A to 4B

Referring to FIGS. 4A and 4B, a second operating mode of the microsystem 1 according to its first embodiment will now be described.

In this second operating mode, the object 3 is not supported, but carried, by the microsystem 1. In which case, the microsystem 1 is advantageously affixed on the object 3 in a configuration where the transducer 11 is deflected towards the centre of the first cavity 13, so that the free area 121 of the diaphragm 12 is deformed in a direction opposite to the centre of the first cavity 13 and reduces the volume of the second cavity 20. At this point, the pressure inside the second cavity 20 is substantially equal to the ambient pressure. The deflection of the transducer 11 is related to its loading, in particular by application of an electric voltage. When the loading of the transducer 11 is reduced or cancel subsequently, the transducer 11 recovers its off-load position through a movement in a direction opposite to the centre of the first cavity 13. The free area 121 of the diaphragm 12 is then moved towards the centre of the first cavity 13. Thus, the volume of the second cavity 20 is increased, and the pressure inside the cavity 20 is reduced in comparison with the ambient pressure. Thus, a pressure difference has been created which allows holding, and possibly carrying, the object 3, while the transducer 11 itself is not loaded.

Consider the particular case wherein the object 3 is based on silicon and is in the form of a parallelepiped with large surfaces substantially equal to 100 cm² and with a thickness of 700 microns. In normal conditions of gravity and of atmospheric pressure, the weight of this object 3 is about 1.59 mN. For the microsystem 1 to allow carrying the object 3, the counter-pressure force exerted on the object 3 by the aforementioned pressure difference must be higher than the weight of the object 3. Still in the considered particular case, considering a second cavity 20 having a substantially cylindrical shape with a radius R equal to 100 microns and with a height H equal to 200 microns, the volume of the second cavity 20 has a value substantially equal to 8.10⁻¹² m³, when the free area 121 of the diaphragm 12 is not deformed, besides a volume variation of 4.10⁻¹² m³, namely half 8.10⁻¹² m³, allow creating, with respect to the ambient pressure equal to the atmospheric pressure, a pressure difference exerting on the object 3 obstructing the second cavity 20 a counter-pressure force substantially equal to 3.56 mN, higher than 1.59 mN, i.e. a counter-pressure force allowing resisting the weight of the object 3 in a relatively comfortable manner. It goes without saying, in particular in light of the appended illustrations, that a variation for half the volume of the second cavity 20 could be reached.

Thus, the microsystem 1 allows holding the object 3, including when the object 3 does not rest on the microsystem 1, i.e. when its weight is not supported by the microsystem 1. Thus, the microsystem 1 could grasp an object 3 with a given determined weight from atop (with respect to the force of gravity), hold it for a determined period of time, for example the time to move the object from its initial position up to another position (and without this requiring a loading, in particular electric, of the electromechanical transducer 11), and then release the object 3, for example once the latter has reached its destination. The microsystem 1 herein finds a particularly advantageous application in so-called “pick-and-place” machines.

An embodiment of the invention that is more specific than those described hereinabove is illustrated in FIG. 5 wherein the same references as in FIG. 1A refer to the same objects.

First of all, one could observe that the illustrated electromechanical transducer 11 comprises a support 305 also referred to as beam and a piezoelectric material 302 configured to deform the beam 305 when an electric voltage is applied thereto. The term beam 305 does not limit the shape of this support. In this example, the beam 305 forms a disk. The cowl 18 or the first cavity 13 of the electromechanical microsystem 1 is intended to be fastened on a support or a frame.

The piezoelectric material 302 is located thereon beneath the material forming the beam 305 or, equivalently, above the neutral fibre of the transducer 11. As this will appear clearly in light of the description hereinbelow of the method for manufacturing the microsystem illustrated in FIG. 5, note herein that it is easy to obtain a reverse configuration wherein the piezoelectric material 302 would be located above the material forming the beam or, equivalently, above the neutral fibre of the transducer 11. It is thanks to this alternative that a piezoelectric material whose deformation is not sensitive to the polarisation of the electric current flowing therethrough still allows deforming the beam 305 in either direction.

In FIG. 5, the piezoelectric material 302 is therefore located under the beam 305, i.e. it is located between the beam 305 and the diaphragm 12. When an electric voltage is applied to the piezoelectric material 302, it retracts and displaces the beam 305 with it. The beam 305 bends downwards, displacing with it the area of the diaphragm 12 connected to the beam 305. In turn, by volume conservation, the free area 121 of the diaphragm moves upwards. This case corresponds to that illustrated in FIG. 3B. The ends of the beam 305 remain fixed. More particularly, its ends may be trapped between the cowl 18 on the one hand and a fixed wall 306 of the first cavity 13 on the other hand, and also possibly with an optional strut 19. The strut 19 may be in the form of a pillar or a low wall. It allows supporting the diaphragm 12. The deformable medium 14 surrounds this strut 19. This strut 19 serves as a pillar inside the cavity 13. Where appropriate, the strut 19 allows, for example together with the portion of the cowl 18 over it, stiffening a contour of the electromechanical transducer 11, so that its deformation is converted, as much as possible, into a deformation of the diaphragm. It is possible to provide for several struts 19.

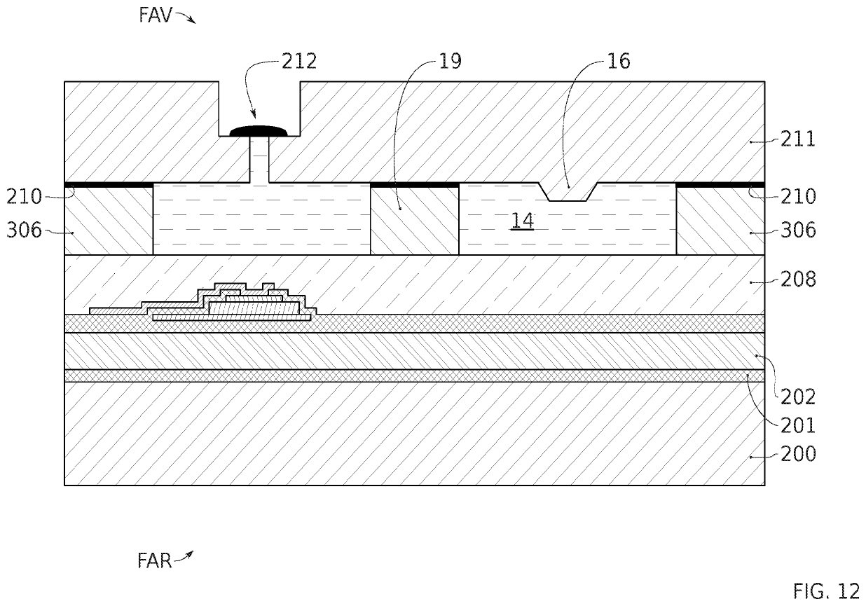

More particularly, FIG. 5 illustrates an embodiment of the invention that has been obtained through deposition and etching steps which could be considered as ordinary in the microelectronics industry. More particularly, the electromechanical microsystem 1 according to the embodiment illustrated in FIG. 5 has been obtained through the succession of steps illustrated by FIGS. 6 to 12.

This manufacturing method comprises:
a step of forming, over a substrate 200, at least one portion of said at least one electromechanical transducer 11, then
a step of depositing the deformable diaphragm 12, then
a step of forming at least one first open cavity 13 over the deformable diaphragm 12, then
a step of filling with the deformable medium 14 and closing the first cavity 13, and
a step of etching the substrate 200 to form a second open cavity 20 and a front face FAV of the electromechanical microsystem 1 as illustrated in FIG. 5 comprising the second cavity 20.

### Examples of Steps of Manufacturing Methods

We describe the aforementioned manufacturing method hereinbelow.

The first step of this method is illustrated in FIG. 6. It consists in providing a substrate 200 over which extends a stack of layers which may successively comprise, starting from one face of the substrate 200:
a first insulating layer 201, for example based on silicon oxide, which may be deposited by Plasma-Enhanced Chemical Vapour Deposition (or PECVD),
a layer 202 intended to form the beam 305 of the electromechanical transducer 11, this layer 202 being for example based on amorphous silicon and may be deposited by Chemical Vapour Deposition (or CVD) at subatmospheric pressure (or LPCVD) or through the use of SOI-type (standing for Silicon On Insulator) structure,
a second insulating layer 203, for example based on silicon oxide and which may be deposited by PECVD,
a layer 204 intended to form a so-called lower electrode, for example based on platinum and which may be deposited by Physical Vapour Deposition (or PVD),
a layer 205 made of a piezoelectric material, for example based on PZT, and which may be deposited through sol-gel process, and
a layer 206 intended to form a so-called upper electrode, for example based on platinum and which may be deposited by PVD.

The second step of the method for manufacturing the electromechanical microsystem 1 as illustrated in FIG. 5 is illustrated in FIG. 7. It comprises:
etching of the layer 206 so as to form the upper electrode 301 of the electromechanical transducer 11,
etching of the layer 205 so as to form the piezoelectric elements 302 of the electromechanical transducer 11, and
etching of the layer 204 so as to form the lower electrode 303 of the electromechanical transducer 11.

Note that each of these etchings may be carried out by lithography, and preferably by plasma etching, or by a wet chemical process.

The third step of the method for manufacturing the electromechanical microsystem 1 as illustrated in FIG. 5 is illustrated in FIG. 8. It comprises:
the deposition of a passivation layer 207, for example based on silicon oxide and/or silicon nitride, may be deposited by PECVD,
opening, through the passivation layer 207, of an area for resuming contact per electrode, this opening may be carried out for example by lithography, and preferably by plasma etching, or by a wet chemical process,
the deposition of a layer intended to form an electric line 304 per electrode, the layer being for example based on gold and may be deposited by PVD, and
etching of the previously deposited layer so as to form an electric line 304 per electrode, this etching being carried out for example by lithography, and preferably by plasma etching, or by a wet chemical process.

The fourth step of the method for manufacturing the electromechanical microsystem 1 as illustrated in FIG. 5 is illustrated in FIG. 9. It comprises the deposition of a polymer-based layer 208 intended to form the deformable diaphragm 12. For example, this layer 208 is deposited by spin coating. For example, the polymer based on which the layer 208 is formed is based on PDMS.

The fifth step of the method for manufacturing an electromechanical microsystem 1 as illustrated in FIG. 5 is illustrated in FIG. 10. It comprises the formation of at least one spacer 306 intended to form at least one portion of said at least one lateral wall 133 of the cavity 13. It may further comprise the formation of a strut 19. This strut 19 allows supporting the diaphragm 12 and fixing the electromechanical transducer 11 by one of its sides The deformable medium 14 surrounds this strut 19. This strut 19 serves as a pillar inside the cavity 13. The formation of the spacer(s) 306 and of the possible strut 19 may comprise rolling of a photosensitive material based on which the spacer(s) are formed, insulation, and then the development of the photosensitive material. Said photosensitive material may be based on a polymer, and in particular based on Siloxane. Rolling of the photosensitive material may comprise rolling of a dry film of said material.

The sixth step of the method for manufacturing an electromechanical microsystem 1 as illustrated in FIG. 5 is illustrated in FIG. 11. According to an optional embodiment, this step comprises the deposition of glue 210 at the top of each spacer 306, and where appropriate of the possible struts 19, this deposition could be carried by screen-printing or by dispensing. It comprises fastening, for example by gluing, at the top of the spacer(s) (possibly through the glue 210), a second substrate 211 which could be structured so as to comprise at least one amongst a through vent 212 and a bottom stop 16 as described hereinabove. In an alternative embodiment, depending on the nature of the spacer, the latter could serve as glue. Upon completion of this sixth step, the first cavity 13 is formed which is open by at least one through vent 212.

The seventh step of the method for manufacturing an electromechanical microsystem 1 as illustrated in FIG. 5 is illustrated in FIG. 12. It comprises filling, preferably under vacuum, the first cavity 13 with the deformable medium 14 as described hereinabove, for example by dispensing through the through vent 212. It also comprises the tight closure of the at least one through vent 212, for example by dispensing a sealing material 213 at the mouth of each through vent 212, the sealing material 213 being for example based on an epoxy glue.

An additional step allows obtaining the electromechanical microsystem 1 as illustrated in FIG. 5. It comprises etching of the substrate 200. This etching may be carried out by lithography, and preferably by plasma etching, or by a wet chemical process. Afterwards, it comprises etching of the layer 202 and of the insulating layers 201, 203 so as to form at least one beam 305 of the electromechanical transducer 11, expose a portion of the deformable diaphragm 12 and form all or part of the lateral wall 22 of the second cavity 20.

Note that, following the above-described steps of manufacturing the electromechanical microsystem 1 as illustrated in FIG. 5, the lateral wall 22 of the second cavity 20 is in the form of a stack, for example annular, extending, directly or indirectly, from the deformable diaphragm 12 opposite to the first cavity 13 while successively presenting the material of the insulating layer 201, the material forming the beam 305, the material of the insulating layer 203 and the material forming the substrate 200.

### Other Embodiments

Using the principles, the features and the technical effects mentioned with reference to the above-described embodiments, many variants may be considered. Some of its variants re briefly disclosed hereinbelow. All features and all technical effects mentioned in the following examples and in the above-described examples may be combined.

Shape of the Free Area 121 and of the Electromechanical Transducer 11

The shapes of the free area 121 of the diaphragm 12 may be adapted with a great freedom according to the pursued objectives. For example, these objectives concern the shape that should be conferred on the opening 23 of the second cavity 20.

The free area 121 may have a disk-like shape or an oblong or ellipsoidal shape.

Alternatively, the free area 121 may have a polygonal shape, for example a square shape or form an open contour, for example “U”-like shaped.

Like the shape of the free area 121, the shape of the electromechanical transducer 11 may be adapted as desired.

Number and Relative Arrangement of the Electromechanical Transducers

In the embodiments illustrated in FIGS. 1A and 2A, one single electromechanical transducer 11 and two electromechanical transducers 11a and 11b are represented, respectively.

Nevertheless, for each of these embodiments, it is possible to provide for several electromechanical transducers for the same electromechanical microsystem 1.

Of course, the number of electromechanical transducers 11 may be greater than two.

The electromechanical transducers may be loaded simultaneously or successively.

The amplitude of deformation of the diaphragm induced by each electromechanical transducer may be identical or different.

The presence of several electromechanical transducers in the same electromechanical microsystem 1 allows for various operating modes.

According to one embodiment, the electromechanical transducers may be configured so that, under load, their movable portions induce deformations of the free area 121 in the same direction. The overall deformation of the diaphragm then results from a cumulated displacement of the movable portions of these electromechanical transducers. This allows increasing even more the amplitude of variation of the volume of the second cavity 20.

Moreover, in the case where the electromechanical transducers could be activated independently from each other or successively, the electromechanical microsystem 1 then has a step-by-step operation. This allows controlling the variation of the volume of the second cavity 20 with an even greater accuracy.

According to another embodiment, which could be combined with the step-by-step embodiment, at least some of the electromechanical transducers may be configured so that, under load, they induce a deformation of the diaphragm in two opposite directions, as illustrated in FIG. 2A. Hence, these two electromechanical transducers are antagonist. Thus, at least one of these electromechanical transducers allows deforming the diaphragm according to a first direction and at least another one of these electromechanical transducers allows deforming the diaphragm according to a second direction opposite to the first direction. This allows increasing even more the amplitude of variation of the volume of the second cavity.

The invention is not limited to the previously-described embodiments and extends to all embodiments covered by the claims.

Many applications of the electromechanical microsystem 1 may be considered. For example, the electromechanical microsystem 1 may be arranged in a microbarometer, in a system for self-assembling microelectronic components or in a vibratory, and possibly acoustic, diaphragm system.

1. An electromechanical microsystem comprising:
at least one electromechanical transducer comprising a portion movable between a balance position, off-load, and an out-of-balance position, under load,
at least one deformable diaphragm,
a first deformable cavity, delimited by walls, at least one portion of the deformable diaphragm forming at least one portion of a first wall selected amongst said walls of the first cavity, the first cavity being configured to hermetically contain a deformable medium capable of keeping a substantially constant volume under the action of a change of an external pressure exerted on the deformable medium through one of the walls of the first cavity,
at least one second deformable cavity, having a variable volume delimited by walls and an opening,
wherein the movable portion of the electromechanical transducer is configured so that its movement depends on said change in the external pressure, or conversely its movement induces a change in the external pressure in the first cavity,
wherein said at least one portion of the deformable diaphragm has at least one free area freely deformable elastically, as a function of said change in the external pressure, and
wherein at least one portion of a first wall selected amongst said walls of the second cavity is formed by at least one portion of said at least one free area of the diaphragm, so that a change in the external pressure in the first cavity induces a variation of the volume of the second cavity or conversely a variation of the volume of the second cavity induces a change in the external pressure in the first cavity,
wherein the opening of the second cavity is intended to be alternately obstructed and cleared by an object, and
the electromechanical microsystem further comprising a flexible layer configured to be interposed between at least one of the walls of the second cavity and a portion of the object intended to obstruct the second cavity.

2. The electromechanical microsystem according to claim 1, wherein, the diaphragm having an inner face configured to be in contact with the deformable medium and an outer face, the inner face of the diaphragm forms at least one portion of the first wall of the first cavity and the outer face of the diaphragm forms at least one portion of the first wall of the second cavity.

3. The electromechanical microsystem according to claim 1, wherein an area over which the first wall of the second cavity extends is devoid of any movable portion of an electromechanical transducer.

4. The electromechanical microsystem according to claim 1, wherein the second cavity comprises, amongst these walls, a lateral wall extending from a perimeter of its first wall opposite to the first cavity.

5. The electromechanical microsystem according to claim 4, wherein the lateral wall defines a distal end and the opening is formed at least partially by the distal end of the lateral wall.

6. The electromechanical microsystem according to claim 1, wherein the first wall of the second cavity is formed by only a portion of said at least one free area of the diaphragm, the second cavity comprising a lateral wall extending from said at least one free area of the diaphragm.

7. The electromechanical microsystem according to claim 1, comprising a plurality of second cavities separated from each other by a non-zero distance.

8. The electromechanical microsystem according to claim 1, wherein the movable portion of at least one electromechanical transducer is configured so that it loading induces its movement towards the centre of the first cavity, a deformation of the free area of the deformable diaphragm opposite to the centre of the first cavity and therefore a decrease in the volume of the second cavity and so that a subsequent absence of loading induces its movement opposite to the centre of the cavity, a deformation of the free area of the deformable diaphragm towards the centre of the first cavity and therefore an increase in the volume of the second cavity.

9. The electromechanical microsystem according to claim 1, wherein said at least one electromechanical transducer is configured so as to selectively induce a decrease and an increase of the volume of the second cavity.

10. The electromechanical microsystem according to claim 1, wherein said at least one electromechanical transducer is configured to exert on the deformable medium, when loaded, a determined change in the external pressure and wherein the shape and/or the dimensions of said at least one free area of the deformable diaphragm are configured to induce, as a function of said determined change in the external pressure, a variation of the volume of the second cavity capable of generating a force for sucking an object obstructing the opening, said sucking force being higher than the weight of the object.

11. The electromechanical microsystem according to claim 1, wherein the deformable diaphragm is configured so that its free area could be deformed with an amplitude of at least 50 μm, and possibly about 100 μm.

12. A set comprising an electromechanical microsystem according to claim 1, and at least one object intended to obstruct the opening.

13. The set according to claim 12, wherein the lateral wall defines a distal end and the opening is formed at least partially by the distal end of the lateral wall, and wherein the distal end of the lateral wall is shaped so that, when the object obstructs the opening, a deformation of the deformable diaphragm tending to increase the volume of the second cavity creates a decrease in the pressure in the second cavity.

14. A method for manufacturing an electromechanical microsystem according to claim 1, comprising:
a step of forming, over a substrate, at least one portion of said at least one electromechanical transducer, then
a step of depositing the deformable diaphragm, then
a step of forming at least one first open cavity over the deformable diaphragm, then
a step of filling with the deformable medium and closing the first cavity, and
a step of etching the substrate to form a second open cavity and a front face of the electromechanical microsystem comprising the second cavity.
